(19) United States
(12) Patent Application Publication
(10) Pub. No.: US 2010/0059842 A1
(43) Pub. Date: Mar. 11, 2010

(54) IMAGE SENSOR AND MANUFACTURING METHOD THEREOF

(76) Inventor: Ha-Kyu Choi, Yongin-si (KR)

Correspondence Address: SHERR & VAUGHN, PLLC, 620 HERNDON PARKWAY, SUITE 320, HERNDON, VA, 20170, US

(21) Appl. No.: 12/549,619

(22) Filed: Aug. 28, 2009

(30) Foreign Application Priority Data
Sep. 5, 2008 (KR) 10-2008-0087610

(51) Int. Cl. H01L 31/0232; H01L 31/18

(52) U.S. Cl. 257/432; 438/70; 257/E31.127; 257/E21.211

(57) ABSTRACT

A manufacturing method of an image sensor includes forming a photodiode region by implanting impurity ions in a semiconductor substrate, forming an interlayer dielectric over the semiconductor substrate having the photodiode region, forming a recess in the interlayer dielectric to expose the photodiode region, vapor-depositing a plurality of refractive layers over an inner surface of the recess, each refractive layer having a different refractive index, forming a color filter layer over the interlayer dielectric having the plurality of refractive layers, and forming a micro lens over the color filter layer.

The present application claims priority under 35 U.S.C. 119 to Korean Patent Application No. 10-2008-0087610 (filed on Sep. 5, 2009), which is hereby incorporated by reference in its entirety.

### BACKGROUND

An image sensor is a semiconductor device that converts an optical image into an electric signal. A charge coupled device (CCD) and a complementary metal oxide silicon (CMOS) device are examples of image sensors. An image sensor includes a light receiving area, including a photodiode that senses light, and a logic area for processing the sensed light into an electric signal data. That is, the image sensor is a device which captures an image, from the light incident to the light receiving area, using the photodiode in each unit pixel, and one or more transistors.

FIG. 1 is a sectional view of an image sensor according to the related art. More specifically, FIG. 1 shows a unit pixel included in the light receiving area of the image sensor. Referring to FIG. 1 the image sensor includes at least one photodiode 120 formed in a semiconductor substrate 110, an interlayer dielectric 130 having a multilayer structure and including metal lines 135, a color filter layer 140 formed over the interlayer dielectric 130 corresponding to the at least one photodiode 120, a planarization layer 150 formed over the color filter layer 140, and a micro lens 160 formed over the planarization layer 150 corresponding to the color filter layer 140.

Incident light properly passed through the micro lens 160 and filtered by the color filter layer 140 is received by the photodiode 120 which corresponds to the color filter layer 140. On the other hand, incident light passed through an edge part of the micro lens 160 and filtered by the color filter layer 140 may be deflected to a neighboring photodiode, thereby inducing cross talk.

### SUMMARY

Embodiments relate to a semiconductor device, and more particularly, to an image sensor capable of avoiding loss of light and restraining cross talk, and a manufacturing method thereof. Embodiments relate to an image sensor which may include a photodiode formed in a photodiode region formed in a semiconductor substrate, an interlayer dielectric formed over a portion of the photodiode and semiconductor substrate, a plurality of refractive layers formed within the interlayer dielectric, each refractive layer having a different refractive index, a color filter layer disposed over the interlayer dielectric and over the plurality of refractive layers, and a micro lens disposed over the color filter layer.

Embodiments relate to a method for manufacturing an image sensor which may include forming a photodiode region by implanting impurity ions in a semiconductor substrate, forming an interlayer dielectric over the semiconductor substrate having the photodiode region, forming a recess in the interlayer dielectric to expose the photodiode region, vapor-depositing a plurality of refractive layers over an inner surface of the recess, each refractive layer having a different refractive index, forming a color filter layer over the interlayer dielectric having the plurality of refractive layers, and forming a micro lens over the color filter layer.

### DRAWINGS

FIG. 1 is a sectional view showing an image sensor according to a related art.

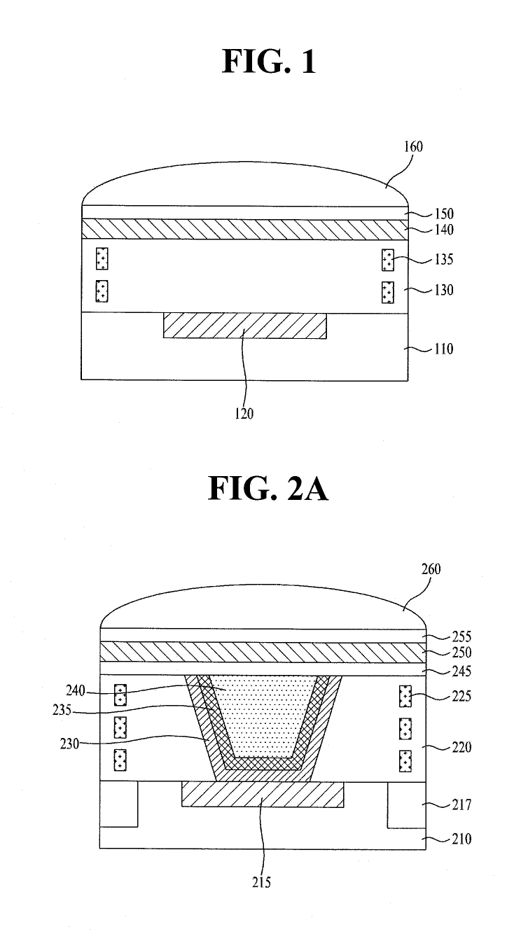

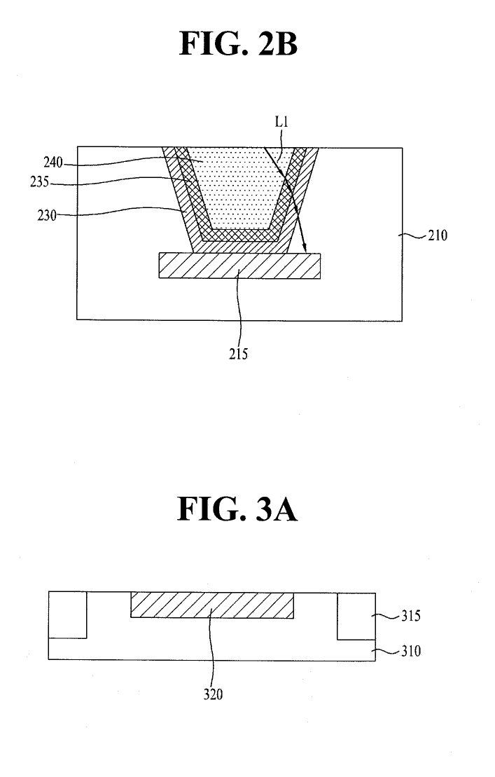

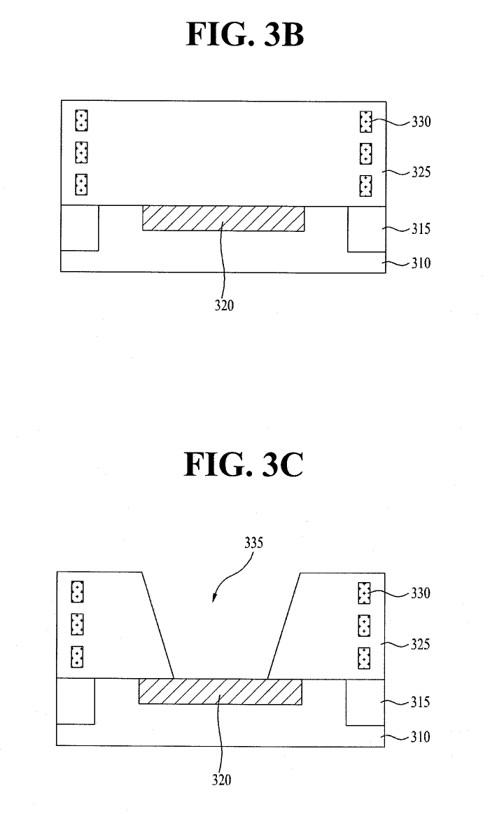

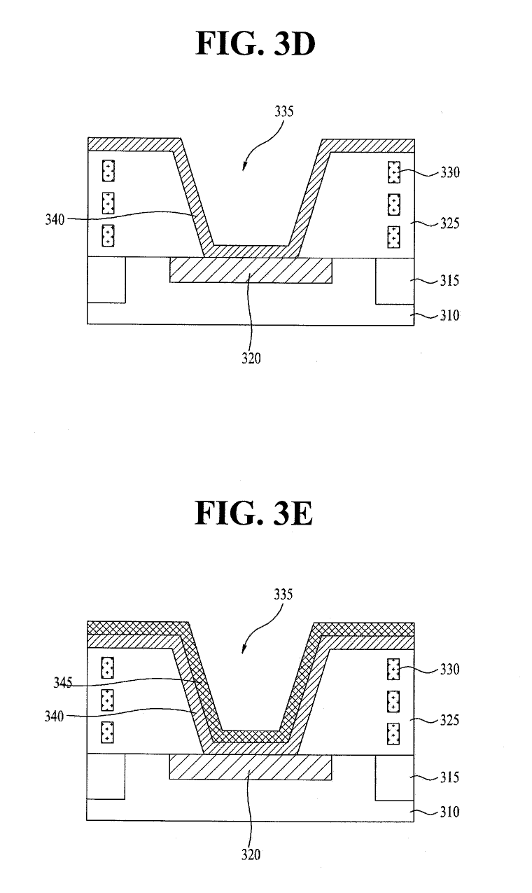

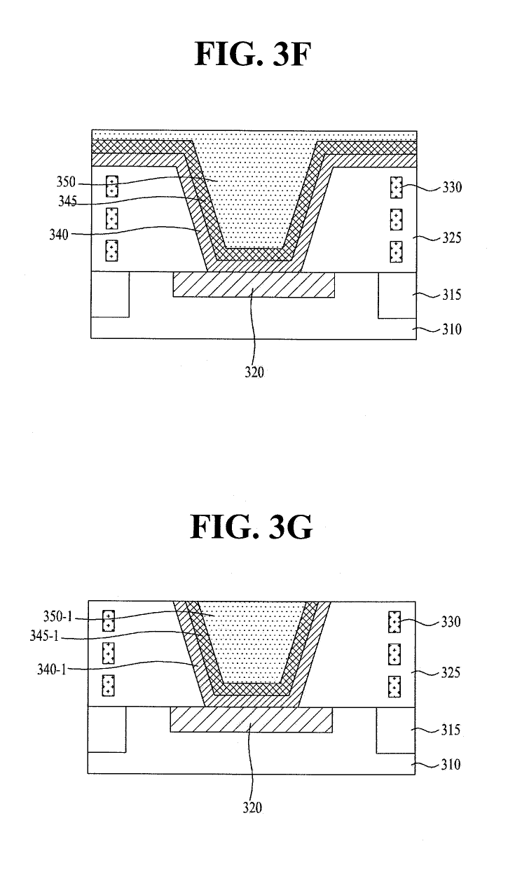

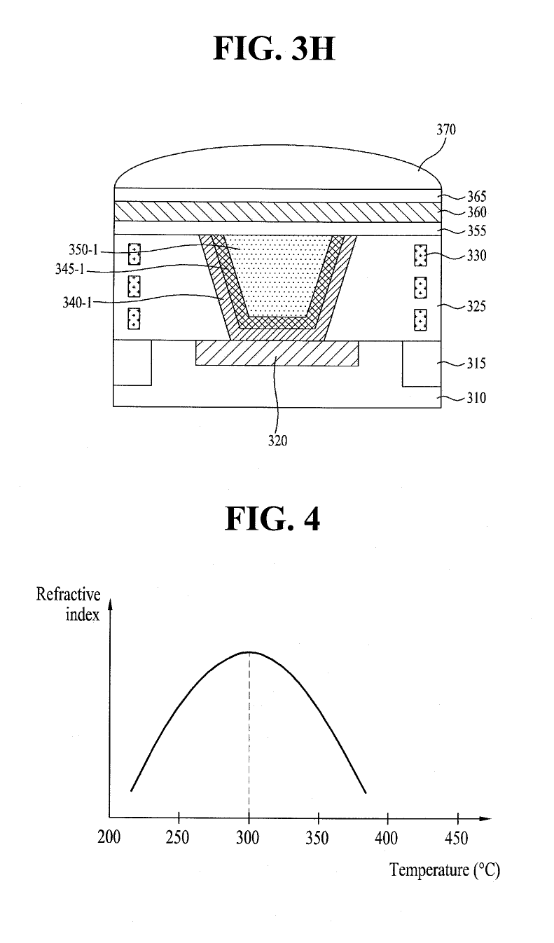

Example FIG. 2A is a sectional view of an image sensor according to embodiments.

Example FIG. 2B is a view showing refraction of light in a plurality of refractive layers shown in example FIG. 2A.

Example FIG. 3A to FIG. 3H are views showing the processes of a method for manufacturing the image sensor according to embodiments.

Example FIG. 4 is a graph showing the relationship between a vapor-deposition temperature and an index of refraction.

### DESCRIPTION

Example FIG. 2A is a sectional view of an image sensor according to embodiments, showing a unit pixel of a light receiving area of the image sensor. Referring to example FIG. 2A, the image sensor may include a substrate 210, a device isolation layer 217, a unit photodiode 215, an interlayer dielectric 220, a recess, a metal line 225, a plurality of refractive layers 230, 235 and 240, a passivation layer 245, a color filter layer 250, a planarization 255, and a micro lens 260.

The device isolation layer 217 may be formed in a semiconductor substrate, thereby defining an active region and a device isolation region. The unit photodiode 215 may be formed by implanting impurity ions such as N-type impurity ions in the active region. The interlayer dielectric 220 may have a multilayer structure including a plurality of dielectric layers made using undoped silicate glass (USG) or tetraethoxysilane (TEOS). The metal line 225 may be disposed in the interlayer dielectric 220.

The recess may be formed in the interlayer dielectric to expose a region corresponding to the unit photodiode 215. The recess may be in the form of a hole or a funnel, with the diameter of the hole or funnel gradually decreasing with decreasing distance from the photodiode.

The plurality of refractive layers 230, 235 and 240 may be layered in sequence over an inner surface of the recess, thereby filling the recess. The refractive layers 230, 235 and 240 may have different refractive indexes. For example, the refractive index of the refractive layers 230, 235 and 240 may increase toward the center of the recess.

Specifically, the refractive layers 230, 235 and 240 may include a first refractive layer 230 vapor-deposited over the inner surface of the recess to have a first refractive index n1, a second refractive layer 235 vapor-deposited over the first refractive layer 230 to have a second refractive index n2, and a third refractive layer 240 vapor-deposited over the second refractive layer 235 to have a third refractive index n3. Here, the second refractive index n2 may be higher than the first refractive index n1 and lower than the third refractive index n3 (n1<n2<n3).

The passivation layer 245 may be formed over the whole surface of the interlayer dielectric 220 where the refractive layers 230, 235 and 240 are formed, to protect the device from moisture and scratches. The color filter layer 250 may be formed over the passivation layer 245 on a position corresponding to the unit photodiode region 215. The planarization layer 255 may be formed over the color filter layer 250. The micro lens 260 may be formed over the planarization layer 255 on a position corresponding to the color filter layer 250.

Example FIG. 2B shows light being refracted by the plurality of refractive layers 230, 235 and 240. Referring to example FIG. 2B, light L1 passing through the third, second and first refractive layers 240, 235 and 230, which have different refractive indexes, may be refracted or totally reflected by the respective refractive layers, thereby being finally received by the unit photodiode 215. In general, light is refracted at an interface between two different mediums, and the refractive angle may be determined by refractive indexes of the two mediums. Also, the refractive index is determined by density of the respective mediums. The thicknesses of the refractive layers 230, 235 and 240, which may be all the same or different, have an influence on a distance the refracted light advances from the respective layers. For example, the distance the light advances when refracted by the second refractive layer 235 is proportional to the thickness of the second refractive layer 235.

Example FIG. 3A through example FIG. 3H are sectional views of only the unit pixel to explain a method for manufacturing the image sensor according to embodiments. Referring to example FIG. 3A, first, a device isolation layer 315 which defines an active region and a device isolation region may be formed over a semiconductor substrate 310. The device isolation layer 315 may be formed using a recessed-local oxidation of silicon (R-LOCOS) method or a shallow trench isolation (STI) method. In addition, impurity ions such as N-type impurity ions may be selectively implanted in the active region, thereby forming a photodiode region 320.

Next, as shown in example FIG. 3B, an interlayer dielectric 325 including a metal line 330 may be formed over the semiconductor substrate 310. The interlayer dielectric 325 may have a multilayer structure including a plurality of dielectric layers including USG or TEOS. For example, after a first interlayer dielectric is formed over the semiconductor substrate 310, a first metal line may be formed over the first interlayer dielectric. Then, a second interlayer dielectric may be formed over the first interlayer dielectric including the first metal line. Such processes may be repeatedly performed, thereby completing the multilayer structure of the dielectric layers including the metal lines. However, the metal lines 330 are not formed on the interlayer dielectric disposed over an upper part of the photodiode region 320 that corresponds to a light receiving path.

Referring to example FIG. 3C, next, a recess 335 may be formed in the interlayer dielectric 325 to expose the photodiode region 320. The recess 335 may be disposed to correspond to the photodiode region 320 of each pixel of the image sensor. More specifically, for example, after a photoresist pattern exposing a portion of the interlayer dielectric 325 corresponding to the photodiode region 320 of each pixel is formed over the interlayer dielectric 325 through a photolithography process, the interlayer dielectric 325 may be etched using the photoresist pattern as a mask. Accordingly, the recess may be formed. Here, the recess 335 may be in the form of a hole or a funnel, with the diameter of the hole or funnel gradually decreasing with decreasing distance from the photodiode

As shown in example FIG. 3D, next, a first refractive layer 340 having a first refractive index n1 may be formed over the whole surface of the interlayer dielectric 325 including the recess 335. More specifically, the first refractive layer 340 may be formed with a first thickness over an inner surface of the recess 335 and an upper surface of the interlayer dielectric 325.

Next, as shown in example FIG. 3E, a second refractive layer 345 having a second refractive index n2 may be formed over a surface of the first refractive layer 340. In addition, as shown in example FIG. 3F, a third refractive layer 350 having a third refractive index n3 may be formed over the second refractive layer 345, such that the recess 335 is filled. Although embodiments have been described to have the first to the third refractive layers 240, 345 and 350 as shown in example FIGS. 3D to 3F, embodiments are not so limited, but may have a plurality of refractive layers formed over an inner surface of a recess.

Example FIGS. 3D to 3F show the processes of forming the plurality of refractive layers 340, 345 and 350 having respectively different refractive indexes in the recess 335 disposed corresponding to the light receiving path. Hereinafter, a method for forming the refractive layers will be described in detail.

An oxide layer such as a TEOS or TEOS-O₃ layer may be used for the refractive layers. First, TEOS may be put in a reactor using an N₂ carrier gas, and the TEOS may be vapor-deposited over the surface of the interlayer dielectric 325 having the recess 335 at a first vapor-deposition temperature T1 for a first processing time so as to have a first thickness d1. Here, the first refractive index n1 of the first refractive layer 340 may be obtained in accordance with density of a material being vapor-deposited at the first vapor-deposition temperature T1.

Example FIG. 4 is a graph showing the relations between the vapor-deposition temperature and the refractive index. In general, the refractive index is increased as the vapor-deposition temperature increases under a predetermined reference temperature, for example 300° C. However, the refractive index is decreased as the vapor-deposition temperature increases over the reference temperature.

After the first refractive layer 340 is completely formed, the vapor-deposition temperature may be changed to a second vapor-deposition temperature T2 to form the second refractive layer 345 over the first refractive layer 340 for a second processing time by a second thickness d2. The second refractive index n2 of the second refractive layer 345 may be obtained in accordance with density of a material being vapor-deposited at the second vapor-deposition temperature T2.

After the second refractive layer 345 is completely formed, the vapor-deposition temperature may be changed to a third vapor-deposition temperature T3 to form the third refractive layer 350 over the second refractive layer 345 for a third processing time by a third thickness d3. The third refractive index n3 of the third refractive layer 350 may be obtained in accordance with density of a material being vapor-deposited at the second vapor-deposition temperature T3.

To minimize loss of the light advancing to the photodiode and cross talk, it may be necessary to adjust the refractive indexes of the refractive layers, such that the light path is guided toward the photodiode, using differences among the refractive indexes. To this end, specifically, the refractive indexes need to be increased in sequence of the refractive layers 340, 345 and 350. That is, the second refractive index n2 is higher than the first refractive index n1 but lower than the third refractive index n3 (n1<n2<n3).

For example, at a temperature area under the reference temperature of about 300° C., the first, second and third refractive layers 340, 345 and 350 may be sequentially vapor-deposited so that the vapor-deposition temperature is gradually increased to be T1<T2<T3. Here, the refractive indexes n1, n2 and n3 may be adjusted by varying the vapor-deposition temperature, such that the light is reflected to the photodiode or totally reflected from the interfaces between the refractive layers 340, 345 and 350.

The vapor-deposition thicknesses d1, d2 and d3 of the refractive layers 230, 235 and 240 may be adjusted according to the processing time, for example, to be all the same or all different. The thickness of the refractive layers 230, 235 and 240 influences the distance the refracted light advances from the different refractive layers. For example, the distance the light advances when refracted by the second refractive layer 235 is proportional to the thickness of the second refractive layer 235.

Different refractive indexes of a plurality of refractive layers can be obtained in the following manner. First, TEOS may be vapor-deposited at a reference vapor-deposition temperature T_{ref} for the first processing time by the first thickness d1, over the surface of the interlayer dielectric 325 formed with the recess 335, thereby forming the first refractive layer 340. Next, the first refractive layer 340 may be annealed at a first annealing temperature Tₐₗ. Therefore, the first refractive layer 340 obtains the first refractive index n1 according to the density determined by the first annealing temperature Ta1.

The second refractive layer 345 may be formed by vapor-depositing TEOS over the first refractive layer 340 at the reference vapor-deposition temperature T_{ref} for the second processing time by the second thickness d2. In addition, the second refractive layer 345 may be annealed at a second annealing temperature Tₐ₂. Therefore, the second refractive layer 345 obtains the second refractive index n2 according to the density determined by the second annealing temperature Tₐ₂.

The third refractive layer 350 may be formed by vapor-depositing TEOS over the second refractive layer 345 at the reference vapor-deposition temperature T_{ref} for the third processing time by the third thickness d3. In addition, the third refractive layer 350 may be annealed at a third annealing temperature Tₐ₃. Therefore, the third refractive layer 350 obtains the third refractive index n3 according to the density determined by the third annealing temperature Ta3.

Here, the first, second and third annealing temperatures Ta1, Ta2 and Ta3 may be higher than the reference vapor-deposition temperature. By setting the second annealing temperature to be higher than the first annealing temperature Ta1 and lower than the third annealing temperature Ta3 (Ta1<Ta2<Ta3), the second refractive index may be controlled to be higher than the first refractive index n1 and lower than the third refractive index n3. Defects generated during formation of the respective refractive layers 340, 345 and 350 may be solved by the annealing process.

Although the three refractive layers 340, 345 and 350 are formed in the recess 335 according to example FIGS. 3D to 3F, embodiments are not so limited.

Next, referring to example FIG. 3G, the interlayer dielectric 325 formed with the refractive layers 340, 345 and 350 may be planarized by chemical mechanical polishing (CMP) and accordingly exposed. After the planarization process, the plurality of refractive layers 340-1, 345-1 and 350-1 fill the recess 335.

Next, referring to example FIG. 3H, a passivation layer 355 may be formed over the interlayer dielectric 325 including the refractive layers 340-1, 345-1 and 350-1, to protect the device from moisture and scratches.

A color filter layer 360 may be formed over the passivation layer 355 to correspond to the photodiode region 320. Next, a planarization layer 365 may be formed over the color filter layer 360, and a micro lens 370 may be formed over the planarization layer 365 to correspond to the color filter layer 360.

According to embodiments, in the light receiving path including the interlayer dielectric 325 which includes the micro lens 370, the color filter layer 360 and the refractive layers 340, 345 and 350, and the photodiode region 320. The plurality of refractive layers 340, 345 and 350 are capable of converting the light path toward the photodiode region 320 through differences in the refractive indexes thereof. Accordingly, loss of light directed to the photodiode region 320 and cross talk may be prevented.

As apparent from the above description, in accordance with an image sensor and a manufacturing method thereof according to embodiments, a light path is deflected towards a photodiode using differences of refractive indexes of a plurality of refractive layers disposed on a light receiving path. Therefore, loss of light and cross talk may be prevented.

In addition, since the different refractive layers are achieved by varying the vapor-deposition temperature and/or annealing temperature, the image sensor may be manufactured using a existing equipment without any additional cost incurred. Furthermore, a multi-film function having varied refractive indexes is obtainable using a single material. Also, a plurality of consecutive refractive layers may be formed by varying the vapor-deposition temperature.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. An apparatus comprising:
a photodiode formed in a photodiode region formed in a semiconductor substrate;
an interlayer dielectric formed over a portion of the photodiode and semiconductor substrate; and
a plurality of refractive layers formed within the interlayer dielectric, each refractive layer having a different refractive index.

2. The apparatus of claim 1, wherein the plurality of refractive layers are arranged so that the refractive indexes increase with increasing distance from the photodiode.

3. The apparatus of claim 1, including a passivation layer formed over the interlayer dielectric.

4. The apparatus of claim 3, wherein the plurality of refractive layers occupy a region extending between a central portion of an upper surface of the photodiode and the passivation layer.

5. The apparatus of claim 4, wherein a width of the region occupied by the plurality of refractive layers increases with increasing distance from the photodiode.

6. The apparatus of claim 5, including a color filter layer disposed over the passivation layer.

7. The apparatus of claim 5, including a micro lens over the color filter layer.

8. A method comprising:
forming a photodiode region by implanting impurity ions in a semiconductor substrate;
forming an interlayer dielectric over the semiconductor substrate having the photodiode region;
forming a recess in the interlayer dielectric to expose the photodiode region;
vapor-depositing a plurality of refractive layers over an inner surface of the recess, each refractive layer having a different refractive index;
forming a color filter layer over the interlayer dielectric having the plurality of refractive layers; and
forming a micro lens over the color filter layer.

9. The method of claim 8, wherein vapor-depositing a plurality of refractive layers includes varying a vapor-deposition temperature.

10. The method of claim 8, wherein vapor-depositing a plurality of refractive layers includes varying an annealing temperature.

11. The method of claim 8, wherein the vapor-deposition of the plurality of refractive layers is performed so that refractive indexes of the vapor-deposited refractive layers sequentially increase.

12. The method of claim 11, wherein the vapor-deposition of the plurality of refractive layers includes:
forming a first refractive layer by vapor-depositing an oxide over a surface of the recess at a first vapor-deposition temperature;
forming a second refractive layer by vapor-depositing an oxide over the first refractive layer at a second vapor-deposition temperature; and
forming a third refractive layer by vapor-depositing an oxide over the second refractive layer at a third vapor-deposition temperature.

13. The method of claim 12, wherein the oxide comprises tetraethoxysilane.

14. The method of claim 12, wherein the oxide comprises tetraethoxysilane-03.

15. The method of claim 12, wherein the second vapor-deposition temperature is higher than a first vapor-deposition temperature and lower than the third vapor-deposition temperature.

16. The method of claim 11, wherein the vapor-deposition of the plurality of refractive layers includes:
forming a first refractive layer by vapor-depositing an oxide over a surface of the interlayer dielectric having the recess, at a reference vapor-deposition temperature;
annealing the vapor-deposited first refractive layer at a first annealing temperature so that the first refractive layer has a first refractive index;
forming a second refractive layer by vapor-depositing an oxide over the first refractive layer at the reference vapor-deposition temperature; and
annealing the vapor-deposited second refractive layer at a second annealing temperature varied from the first annealing temperature, so that the second refractive layer has a second refractive index.

17. The method of claim 16, wherein the second annealing temperature is higher than the first annealing temperature.

18. The method of claim 8, wherein the vapor-deposition of the plurality of refractive layers is performed so that the refractive layers have different thicknesses.

19. The method of claim 8, including forming a passivation layer between the interlayer dielectric layer and the color filter layer.

20. The method of claim 8, including forming a planarization layer between the color filter layer and the micro lens.
